(19) United States
(12) Patent Application Publication
(10) Pub. No.: US 2007/0087457 A1
(43) Pub. Date: Apr. 19, 2007

(54) METHOD FOR INSPECTING AND MENDING DEFECT OF PHOTO-RESIST AND MANUFACTURING PROCESS OF PRINTED CIRCUIT BOARD

(76) Inventors: Tzyy-Jang Tseng, Hsinchu (TW); Cheng-Po Yu, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/164,855

(22) Filed: Dec. 8, 2005

(30) Foreign Application Priority Data
Oct. 12, 2005 (TW) 94135481

(51) Int. Cl. H01L 21/00

(52) U.S. Cl. 438/7

(57) ABSTRACT

A method for inspecting and mending defects of photo-resist is provided. It includes the following steps. First, a substrate having at least one film is provided. Then, a patterned photo-resist layer is formed on the film. Next, an optical inspection procedure is performed to inspect whether the patterned photo-resist layer has defects or not. If the patterned photo-resist layer has defects, the defects are classified into gaps and protrusions and then the gaps and the protrusions are positioned. If the patterned photo-resist layer has defects such as gaps, an ink-jet printing method, for example, is performed on the patterned photo-resist layer to fill the gaps up. If the patterned photo-resist layer has defects such as protrusions, a laser method, for example, is performed on the patterned photo-resist layer to remove the protrusions. So the defects of the patterned photo-resist layer can be mended.

### CROSS-REFERENCE TO RELATED APPLICATION

This application claims the priority benefit of Taiwan application serial no. 94135481, filed on Oct. 12, 2005. All disclosure of the Taiwan application is incorporated herein by reference.

### BACKGROUND OF THE INVENTION

1. Field of Invention

The invention relates to a method for inspecting and mending and a manufacturing process of circuit board, and particularly to a method for inspecting and mending defects of photo-resist suitable for printed circuit boards and a manufacturing process of the printed circuit board.

2. Description of Related Art

With the development of science and technology and the continuous advancement in the living quality, as well as the integration and continuous growth of the 3C industry, the application fields of the integrated circuit (IC) have been broadened to, for example, various electronic devices, such as notebook PCs, cell phones, digital cameras, personal digital assistants (PDAs), printers, disk players and the like. Wherein, the printed circuit boards applied in the integrated circuit may not only be used for electrical connections, but also be used to support the chips or other electronic elements.

FIGS. 1 to 5 show a conventional manufacturing process of a printed circuit board, which are schematic views of a part of the circuits in an area of a printed circuit board. Figure (A) part is a schematic top view, while Figure (B) part is a schematic side view. The conventional manufacturing process of printed circuit board typically comprises the following steps. First, referring to FIG. 1, a substrate 110 is provided. Then, a copper foil 120 is laminated onto the substrate 110 by a lamination process. Next, referring to FIG. 2, a photo-resist layer 130 is coated onto the copper foil 120. Then, referring to FIG. 3, the photo-resist layer 130 is exposed by a mask (not shown) to form a photo-resist pattern 132 corresponding to the pattern of the mask. Thereafter, referring to FIG. 4, a developing process is performed to remove the unexposed portion of the photo-resist layer 130, and leave the exposed photo-resist pattern 132 on the copper foil 120.

Referring to FIG. 4, it should be noted that there may be many defects in the conventional manufacturing process of printed circuit board. For example, the mask itself has scratches or blots or the developing tank of the developing equipment hasn't been washed clean, so that many defects are left on the photo-resist pattern 132 of photo-resist layer 130 after exposure and development, as gaps 134 and protrusions 136 of the photo-resist pattern 132 shown in FIG. 4.

Referring to FIGS. 4 and 5, in the conventional manufacturing process of printed circuit board, however, since the photo-resist layer 130 is not inspected thoroughly after the exposure and development. If the resulted photo-resist pattern 132 has many gaps 134 and protrusions 136, the final copper foil pattern 122 resulted from etching the copper foil 120 through the photo-resist pattern 132 also have many gaps 124 and protrusions 126.

Referring to FIG. 5, when the gaps 124 of the copper foil 120 is too large, the electrical connection between the copper wire 122a and its corresponding connecting point 122b may be cut off. Thereby, this further causes an open circuit between the copper wire 122a and its corresponding connecting point 122b. In contrast, when the protrusions 126 of the copper foil 120 is too large, the electrical connection between the two adjacent copper wires 122a as shown in FIG. 5 may occur via these protrusions 126. Thereby, a short circuit may occur between the two adjacent copper wires 122a.

Therefore, the reliability of the printed circuit board 100 is seriously affected. Especially, when the defects of the copper foil 120 are too many, the chances of causing open or short circuits described above is dramatically increased. Thus, the printed circuit board 100 at the area with open circuit or short circuit formed thereon has to be rejected after the manufacturing process of printed circuit board 100 being completed, and thereby the manufacture cost of the overall printed circuit board 100 is increased.

### SUMMARY OF THE INVENTION

An object of the invention is to provide a method for inspecting and mending a defect of photo-resist, to decrease the manufacture cost of printed circuit board.

Another object of the invention is to provide a manufacturing process of printed circuit board, to decrease the manufacture cost of printed circuit board.

The invention provides a method for inspecting and mending a defect of photo-resist, which is suitable for a manufacturing process of printed circuit board and comprises the following steps. First, a substrate having at least one film is provided. Then, a patterned photo-resist layer is formed on the film. Next, an optical inspection procedure is performed to inspect whether or not the patterned photo-resist layer has defects. After that, the defect of the patterned photo-resist layer, if there is any, is mended.

According to the method for inspecting and mending a defect of photo-resist described in the preferred embodiments of the invention, after the step of inspecting the defect of the patterned photo-resist layer, the method further comprises the steps of: classifying the defect of patterned photo-resist layer and positioning the defect by coordinates, wherein the defect of the patterned photo-resist layer can be classified into a gap and a protrusion.

According to the method for inspecting and mending the defect of photo-resist described in the preferred embodiments of the invention, if the patterned photo-resist layer has the defect of at least one gap, an ink-jet printing method is performed on the patterned photo-resist layer to fill the gap up, wherein the ink-jet printing method includes thermal bubble and piezoelectric ink-jet printing.

According to the method for inspecting and mending the defect of photo-resist described in the preferred embodiments of the invention, if the patterned photo-resist layer has the defects of at least one protrusion, a laser method is performed on the patterned photo-resist layer to remove the protrusion, wherein the laser light includes infrared or ultraviolet rays.

According to the method for inspecting and mending the defect of photo-resist described in the preferred embodiments of the invention, after removing the defects of the patterned photo-resist layer, it further includes: first performing an etching process on the film to pattern the film. Then, the patterned photo-resist layer is removed, wherein the film can be a metal layer.

According to the method for inspecting and mending the defect of photo-resist described in the preferred embodiments of the invention, the patterned photo-resist layer can be formed on the film by, for example, an ink-jet printing method.

The invention further provides a manufacturing process of a printed circuit board, which includes the following steps. First, a substrate having at least one metal layer is provided. Then, a patterned photo-resist layer is formed on the metal layer. Next, an optical inspection procedure is performed to inspect whether the patterned photo-resist layer has a defect or not. Then, the defect of the patterned photo-resist layer, if there is any, is mended. After that, an etching process is performed on the metal layer to pattern the metal layer. Then, the patterned photo-resist layer is removed.

According to the manufacturing process of printed circuit board described in the preferred embodiments of the invention, the procedure after the step of inspecting the defects of patterned photo-resist layer further includes: classifying the defect of patterned photo-resist layer and positioning the defect by coordinates, wherein the defect of the patterned photo-resist layer can be classified into a gap and a protrusion. 8 Para 219 According to the manufacturing process of printed circuit board described in the preferred embodiments of the invention, if the patterned photo-resist layer has the defect by at least one gap, an ink-jet printing method is performed to fill the gap up.

According to the manufacturing process of printed circuit board described in the preferred embodiments of the invention, if the patterned photo-resist layer has the defect by at least one protrusion, a laser method is performed to remove the protrusion.

According to the manufacturing process of printed circuit board described in the preferred embodiments of the invention, the patterned photo-resist layer can be formed on the film by, for example, an ink-jet printing method.

The method for inspecting and mending defects of photo-resist and manufacturing process of the printed circuit board in the invention performs an optical inspection after forming a patterned photo-resist layer to inspect whether the patterned photo-resist layer has defects or not and mend the defects to ensure a good appearance of the patterned photo-resist layer. Therefore, the metal layer circuit pattern resulted from etching the metal layer by using such patterned photo-resist layer can be zero defect, and the conventional open circuit and short circuit hardly occurs. Thereby, the rejection rate of the accomplished printed circuit board is effectively decreased, so as to reduce the overall manufacture cost of the printed circuit board.

The above and other objects, characteristics and advantages of the invention will become more apparent from the following detailed description of specified preferred embodiments with reference to the accompanying drawings.

### BRIEF DESCRIPTION OF THE DRAWINGS

FIGS. 1 to 5 show a conventional manufacturing process of printed circuit board, which are schematic drawings of part of circuits in an area of a printed circuit board, wherein Figure (A) part is a schematic top view, while Figure (B) part is a schematic side view.

FIGS. 6 to 8 show a method for inspecting and mending defects of photo-resist according to an embodiment of the invention, which are schematic drawings of part of circuits in an area of a printed circuit board, wherein Figure (A) part is a schematic top view, while Figure (B) part is a schematic side view.

FIGS. 9 and 1 0 show a schematic view of the patterning of the film.

FIG. 11 shows a method for inspecting and mending defects of photo-resist according to an embodiment of the invention, which is a schematic view with the gaps of patterned photo-resist layer removed.

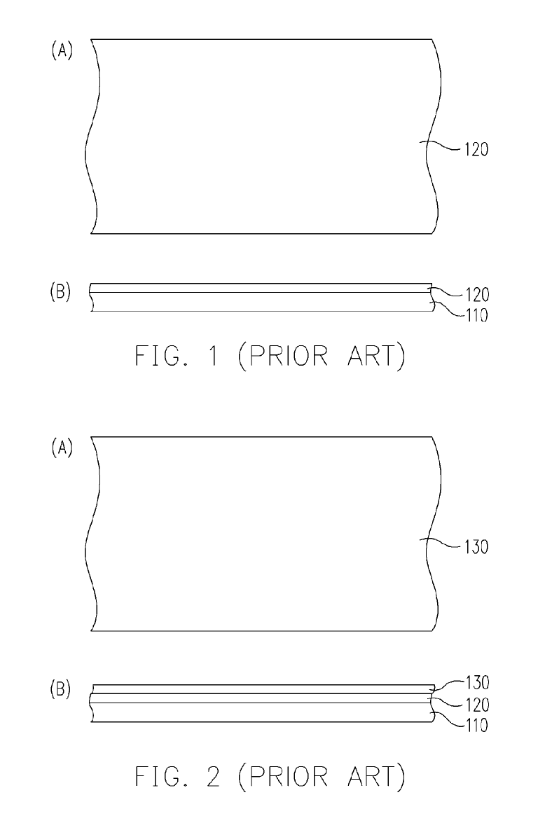

### DESCRIPTION OF EMBODIMENTS

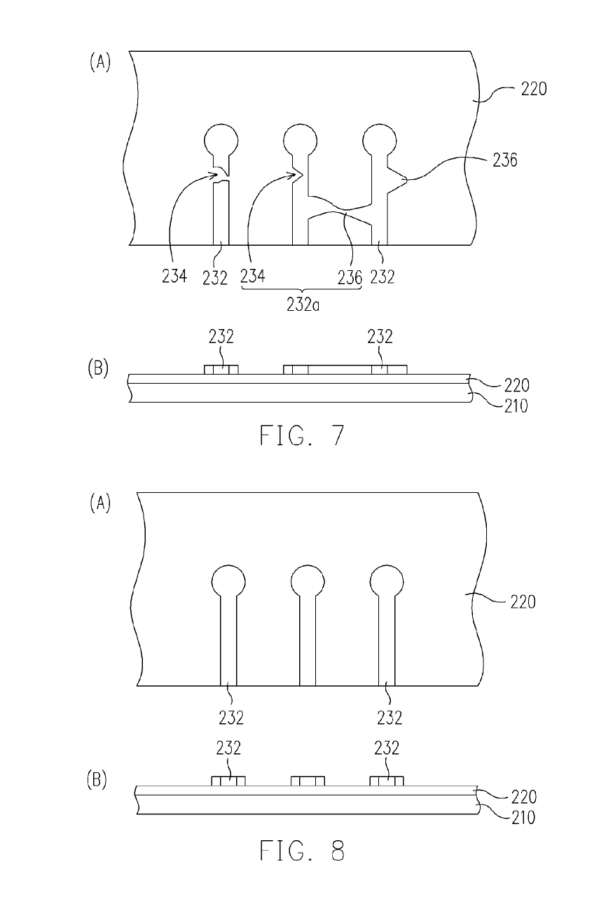

FIGS. 6 to 8 show a method for inspecting and mending defects of photo-resist according to an embodiment of the invention, which are schematic drawings of part of the circuits in an area of a printed circuit board, wherein Figure (A) part is a schematic top view, while Figure (B) part is a schematic side view. The method for inspecting and mending a defect of photo-resist of the invention comprises the following steps. First, referring to FIG. 6, a substrate 210 having at least one film 220 is provided, wherein the film 220 can be, for example, a metal layer, while the metal layer can be, for example, a copper foil. Then, referring to FIG. 7, a patterned photo-resist layer 232 is formed on the film 220 directly, for example, by an ink-jet printing method. Next, an optical inspection procedure is performed to inspect whether the patterned photo-resist layer 232 has any defect 232a or not, for example through an automatic optical inspection machine. After that, referring to FIGS. 7 and 8, when the defect 232a of the patterned photo-resist layer 232 occurs, the defect 232a of the patterned photo-resist layer 232 are mended, so that the appearance of the patterned photo-resist layer 232 is better.

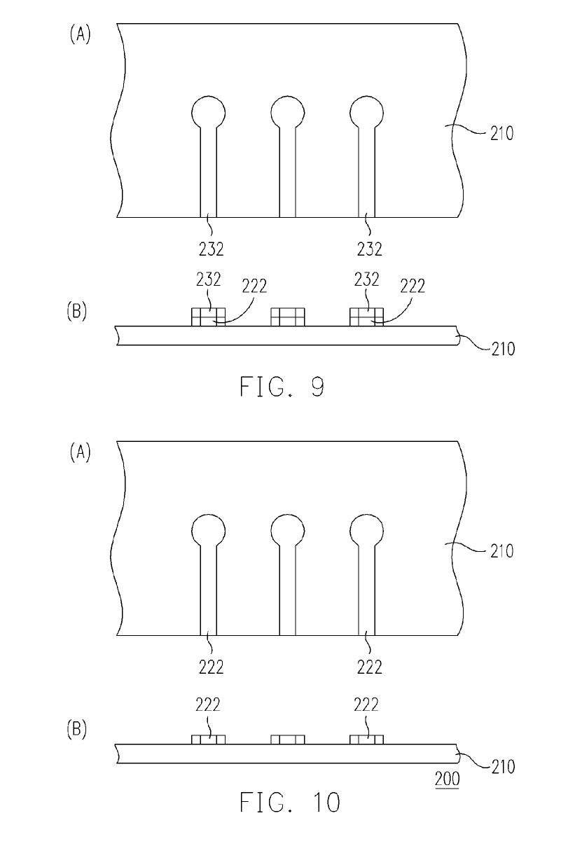

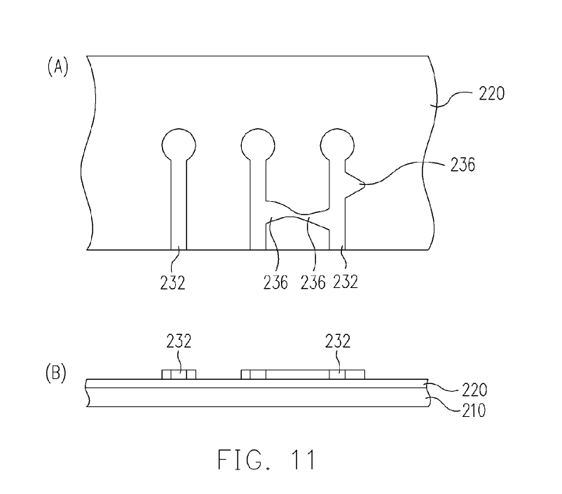

FIGS. 9 to 10 show a manufacturing process of printed circuit board according to an embodiment of the invention, which are schematic drawings of the step of patterning the film. According to an embodiment of the invention, after the defects 232a of patterned photo-resist layer 232 are mended, the method may further includes the following steps. First, referring to FIG. 9, an etching process is performed on the film 220 via the patterned photo-resist layer 232 to pattern the film 220 into a film pattern 222. Then, referring to FIG. 10, the patterned photo-resist layer 232 is removed to expose the film pattern 222, wherein when the film 220 is, for example, a metal layer, the manufacturing process of the printed circuit board 200 of the invention is completed. That is, if the film 220 is for example a metal layer, FIGS. 6 through 10 show schematic views of a manufacturing process of the printed circuit board according to an embodiment of the invention.

According to another embodiment of the invention, after inspecting defects 232a of the patterned photo-resist layer 232, the method further comprises the following steps. Referring to FIG. 7, the defects 232a of the patterned photo-resist layer 232 are classified and positioned by coordinate. According to an embodiment of the invention, the defects 232a of the patterned photo-resist layer 232 may be, for example, classified into gaps 234 and protrusions 236.

FIG. 11 shows a method for inspecting and mending defects of photo-resist according to an embodiment of the invention, which is a schematic view with the gaps of patterned photo-resist layer removed. Referring to FIGS. 7 and 11, according to another embodiment of the invention, if the defects 232a of the patterned photo-resist layer 232 comprise, for example, several gaps 234 as shown in FIG. 7, an ink-jet printing method is performed to fill the gaps 234 up, wherein the ink-jet printing method is, for example, a thermal bubble ink-jet printing method or a piezoelectric ink-jet printing method. If the defects 232a of the patterned photo-resist layer 232 comprise, for example, several protrusions 236 as shown in FIG. 7, a laser method is performed to remove the protrusions 236, wherein the laser light is, for example, an infrared ray or an ultraviolet ray.

It should be noted that although in the manufacturing process of printed circuit board 200 of the invention, a photo-resist layer 230 may probably have many defects 232a, such as the gaps 234 or protrusions 236 of the patterned photo-resist layer 232 shown in FIG. 7, after the exposure via a mask and development due to many process defects (for example the mask itself has scratches or blots or the developing tank of the development equipment hasn't been washed clean). However, according to the present invention, after the photo-resist layer 230 is exposed and developed, an optical inspection is conducted by e.g. an automatic optical inspection machine, to inspect thoroughly the patterned photo-resist layer 232. The defects 232a of patterned photo-resist layer 232 can be mended by, for example, an ink-jet printing method to fill the gaps 234 of the patterned photo-resist layer 232 up, or by, for example, a laser method to remove the protrusions 236 of the patterned photo-resist layer 232.

Next, after an etching process is performed on the film 220 via the patterned photo-resist layer 232 having the defects 232a being mended, the resulted film pattern 222 have fewer defects, and the conventional open circuit and short circuit may hardly occur. Thereby, the rejection rate of the printed circuit board 200 is effectively decreased, so as to reduce the overall manufacture cost of the printed circuit board 200.

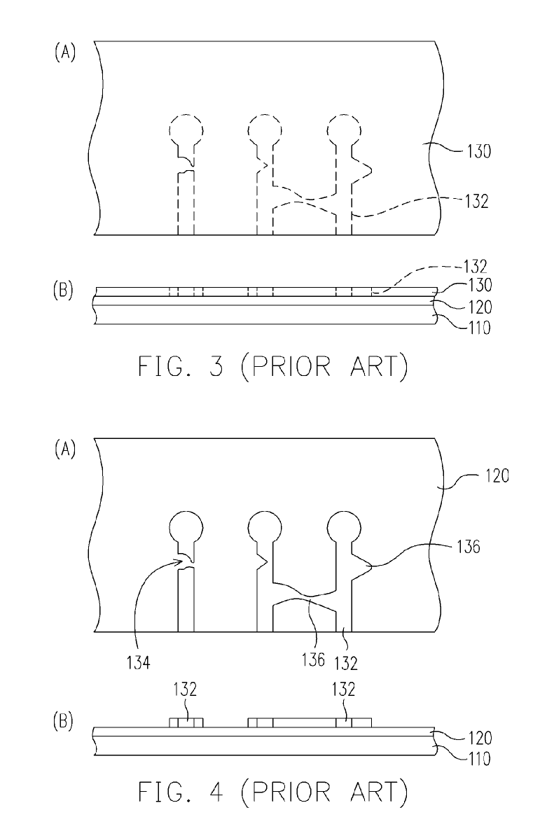

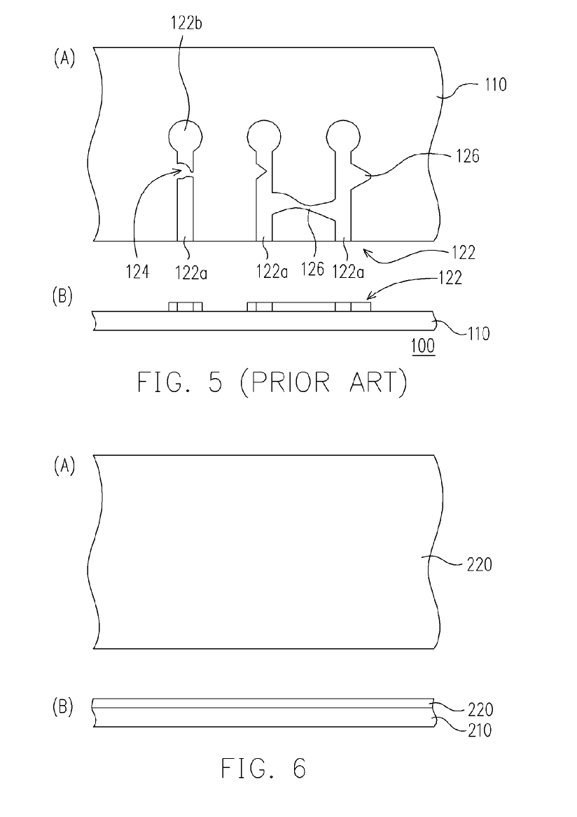

It should be noted that comparing with a conventional photo-resist pattern 1 32 formed by the exposure and development shown in FIGS. 2 to 3, the resulting defects 232a are less than the defects of photo-resist pattern 132, since a patterned photo-resist layer 232 can be directly formed on the film 220 by an ink-jet printing method according to the present invention. Therefore, according to an embodiment of the invention, when a patterned photo-resist layer 232 is formed by an ink-jet printing method according to the present invention, the time of the inspection and mending of defects 232a required by the subsequent optical inspection may be effectively reduced due to its fewer defects 232a, thereby further reducing the manufacture cost of printed circuit board 200.

Of course, in the method for inspecting and mending defects of photo-resist and manufacturing process of printed circuit board according to the present invention, the step of forming a patterned photo-resist layer can also be achieved by exposure and development, and is not limited to the ink-jet printing method. However, when the patterned photo-resist layer is formed by the ink-jet printing method, the time and cost of the subsequent defect inspection and mending may be further reduced due to the fewer defects of the obtained patterned photo-resist layer.

In conclusion, an optical inspection is performed after forming a patterned photo-resist layer to inspect whether the patterned photo-resist layer has defects or not and the defects can be mended, according to the method for inspecting and mending defects of photo-resist and manufacturing process of printed circuit board of the present invention. Because the film is etched by using a patterned photo-resist layer with the defects being mended, the film can have fewer defects, and therefore the open circuit and short circuit hardly occurs. The rejection rate of the printed circuit board is effectively decreased, so as to reduce the overall manufacture cost of the printed circuit board.

Moreover, if a patterned photo-resist layer is formed by an ink-jet printing method according to the present invention, the time and cost of the subsequent defect inspection and mending processes may be effectively reduced due to the fewer defects of the obtained patterned photo-resist layer, thereby the manufacture cost of printed circuit board will be further reduced.

Although the invention has been disclosed above with reference to preferred embodiments, it is to be understood that the invention is not intend to be limited by such description and some changes and modifications can be made by those skilled in the art without departing from the spirit and scope of the invention as defined by the attached claims.

What is claimed is:

1. A method for inspecting and mending a defect of a photo-resist, suitable for a manufacturing process of a printed circuit board, the method comprising:
providing a substrate having at least one film;
forming a patterned photo-resist layer on the film;
performing an optical inspection to inspect whether the patterned photo-resist layer has a defect or not; and
mending the defect of the patterned photo-resist layer if the patterned photo-resist layer has the defect.

2. The method for inspecting and mending defects of photo-resist as claimed in claim 1, wherein after inspecting the defect of the patterned photo-resist layer the method further comprises:
classifying the defect of the patterned photo-resist layer; and
positioning the defects of the patterned photo-resist layer by a coordinate.

3. The method for inspecting and mending defects of photo-resist as claimed in claim 2, wherein the step of classifying the defect of the patterned photo-resist layer comprises classifying the defect of the patterned photo-resist layer into a gap or a protrusion.

4. The method for inspecting and mending defects of photo-resist as claimed in claim 3, wherein the patterned photo-resist layer has the defect by at least one gap, and an ink-jet printing method is performed to fill the gaps up.

5. The method for inspecting and mending defects of photo-resist as claimed in claim 4, wherein the ink-jet printing method comprises thermal bubble ink-jet printing.

6. The method for inspecting and mending defects of photo-resist as claimed in claim 4, wherein the ink-jet printing method comprises piezoelectric ink-jet printing.

7. The method for inspecting and mending defects of photo-resist as claimed in claim 3, wherein the patterned photo-resist layer has the defect by at least one protrusion, and a laser method is performed to remove the protrusions.

8. The method for inspecting and mending defects of photo-resist as claimed in claim 4, wherein the patterned photo-resist layer has the defect by at least one protrusion, and a laser method is performed to remove the protrusions.

9. The method for inspecting and mending defects of photo-resist as claimed in claim 8, wherein the laser light comprises infrared ray.

10. The method for inspecting and mending defects of photo-resist as claimed in claim 8, wherein the laser light comprises ultraviolet ray.

11. The method for inspecting and mending defects of photo-resist as claimed in claim 1, after removing the defect of the patterned photo-resist layer, further comprising:
performing an etching process on the film to pattern the film; and
removing the patterned photo-resist layer.

12. The method for inspecting and mending defects of photo-resist as claimed in claim 1, wherein the film is a metal layer.

13. The method for inspecting and mending defects of photo-resist as claimed in claim 1, wherein the patterned photo-resist layer is formed on the film by an ink-jet printing method.

14. A manufacturing process of printed circuit board, comprising:
providing a substrate having at least one metal layer;
forming a patterned photo-resist layer on the metal layer;
performing an optical inspection to inspect whether the patterned photo-resist layer has a defect or not;
if the patterned photo-resist layer has the defect, mending the defect of the patterned photo-resist layer;
performing an etching process on the metal layer to pattern the metal layer; and
removing the patterned photo-resist layer.

15. The manufacturing process of printed circuit board as claimed in claim 14, wherein after inspecting the defect of the patterned photo-resist layer, the method further comprises:
classifying the defect of the patterned photo-resist layer; and
positioning the defect of the patterned photo-resist layer by a coordinate.

16. The manufacturing process of printed circuit board as claimed in claim 15, wherein the step of classifying the defect of the patterned photo-resist layer comprises classifying the defect of the patterned photo-resist layer into a gap or a protrusion.

17. The manufacturing process of printed circuit board as claimed in claim 16, wherein the patterned photo-resist layer has the defect by at least one gap, and an ink-jet printing method is performed to fill the gap up.

18. The manufacturing process of printed circuit board as claimed in claim 16, wherein if the patterned photo-resist layer has the defect by at least one protrusion, a laser method is performed to remove the protrusion.

19. The manufacturing process of printed circuit board as claimed in claim 17, wherein if the patterned photo-resist layer has the defect by at least one protrusion, a laser method is performed to remove the protrusion.

20. The manufacturing process of printed circuit board as claimed in claim 14, wherein the patterned photo-resist layer is formed on the metal layer by an ink-jet printing method.
